(19) United States
(12) Patent Application Publication
(10) Pub. No.: US 2008/0308150 A1
(43) Pub. Date: Dec. 18, 2008

(54) HOT EMBOSSING OF CONDUCTOR TRACKS ON A PHOTOVOLTAIC SILICON WAFER

(75) Inventor: Ulrich Schindler, Furth/Bayern (DE)

Correspondence Address: HOFFMANN & BARON, LLP, 6900 JERICHO TURNPIKE, SYOSSET, NY, 11791, US

(73) Assignee: LEONHARD KURZ STIFTUNG & CO. KG, Furth (DE)

(21) Appl. No.: 12/136,534

(22) Filed: Jun. 10, 2008

(30) Foreign Application Priority Data
Jun. 14, 2007 (DE) 102007027998.3-33

(51) Int. Cl. H01L 31/0236; B32B 15/00

(52) U.S. Cl. 136/256; 428/457; 156/232

(57) ABSTRACT

There is described a process for the production of conductor tracks (322, 422, 522) on a silicon wafer (1) intended for photovoltaic cells. An electrically conductive transfer layer (22) is transferred completely or region-wise on to the surface of the silicon wafer (1) by an embossing film (2), in particular a hot embossing film.

### BACKGROUND OF THE INVENTION

The invention concerns a process for the production of conductor tracks on a photovoltaic silicon wafer and an embossing film for carrying out the process.

It is known, in the production of photovoltaic cells on the basis of a silicon wafer, to apply the final second electrode in the form of a conductor track to the silicon wafer by means of flat bed screen printing and then to sinter it.

Flat bed screen printing is a time-consuming process and poorly suited to continuous manufacture and inexpensive mass production. In particular in flat bed screen printing the edges of the print image can break away during the printing operation and in particular when printing on abrasive media. That can result in unevenness in the print image of the conductor tracks of the electrodes and thus irregular electrical properties in respect of the electrodes.

DE 689 26 361 T1 describes a process and an apparatus for applying a thin film to a base plate by pressure and hot adhesive. The base plate can be for example an electronic circuit substrate of silicon, gallium-arsenide or the like. The application of vacuum is provided to avoid hollow spaces between the film and the base plate.

### SUMMARY OF THE INVENTION

The object of the present invention is to provide an improved process for applying the conductor tracks to the silicon wafer.

In accordance with the invention that object is attained by the subject-matter of claim 1. There is proposed a process for the production of conductor tracks on a silicon wafer intended for photovoltaic cells, wherein it is provided that an electrically conductive transfer layer is transferred completely or region-wise on to the surface of the silicon wafer by an embossing film, in particular a hot embossing film.

The process according to the invention therefore provides that the formation of the conductor tracks is shifted substantially into a preceding manufacturing step, namely shifted into the manufacture of embossing films, in particular hot embossing films. The production of hot embossing films meets very high demands in terms of register accuracy of the conductor tracks, in which respect the conductor tracks can involve both conductor tracks in the conventional sense and also electrodes or other electrically conducting regions.

Hot embossing films are preferably produced in a roll-to-roll process. In that case important functional parameters of the transfer layer such as material composition, thickness, structure and geometry can be set, while the tolerances which can be achieved are in the range of micrometers to nanometers. In the hot embossing operation, only a few parameters such as temperature, application pressure and residence time (embossing time, speed) have to be controlled to obtain a uniform quality for the transferred layers. In comparison flat bed screen printing is technologically much more complicated and expensive and more difficult to control since, as already mentioned, edges break away or solvents can escape from the print medium during the printing operation.

The embossing film preferably has a carrier layer and a transfer layer arrangement which has at least one transfer layer and preferably an adhesive layer arranged on the side of the transfer layer arrangement, that is remote from the carrier layer. A release layer is preferably arranged between the transfer layer arrangement and the carrier layer. The transfer layer arrangement is applied to the target substrate, with the side that faces away from the carrier layer. In that case the surface of the transfer layer arrangement, that faces away from the carrier layer, is of such a configuration that it adheres to the target substrate, preferably under the action of heat and/or pressure. That surface is thus preferably formed by the surface of a priming layer which is applied on the side of the transfer layer, that faces away from the carrier layer. In the application procedure the embossing film is pressed against the target substrate, in that operation the transfer layer arrangement is caused to adhere to the substrate, for example by heat and/or pressure, and then the carrier layer is removed from the transfer layer arrangement.

The hot embossing film has at least a carrier layer and a transfer layer. In the hot embossing operation a heated embossing punch with raised regions is brought into pressing contact with the hot embossing film disposed between the embossing punch and the substrate to be embossed upon, here the silicon wafer, with the carrier layer facing towards the embossing punch. Regions of the transfer layer, that are arranged under the raised regions, are transferred on to the substrate by pressure and heat, with break lines which follow the edges of the raised regions being formed in the transfer layer. In the regions in which the embossing punch comes into contact with the hot embossing film, the heat and the pressure provide that the adhesion force between the transfer layer arrangement and the substrate to be embossed upon is greater than between the transfer layer arrangement and the carrier layer, for example by a release layer disposed between the carrier layer and the transfer layer arrangement being softened and an adhesive layer disposed between the transfer layer and the substrate to be embossed upon being activated. The embossing punch can therefore determine the geometrical structure of the transferred transfer layer, by virtue of the configuration of its embossing surface. Thus, as described in greater detail hereinafter, it can also be referred to as a structure punch. After the embossing punch has been removed, the regions of the transfer layer, that are transferred by the heated raised regions of the embossing punch, remain on the embossed substrate. The non-heated regions of the transfer layer remain on the carrier film and are removed therewith. Although the hot embossing operation does not require a structured transfer layer, nonetheless it is also possible to provide for the transfer of a structured or pre-structured transfer layer.

The carrier layer of the embossing film is preferably a carrier film of a plastic material, for example polyester, and is preferably of a thickness of less than 200 μm, further preferably between 12 μm and 50 μm. A release layer is preferably disposed between the carrier layer and the transfer layer. The release layer is preferably of a thickness of less than 2 μm and contains wax components which lose their adhesion force in the heating operation and thus facilitate separation of the transfer layer from the carrier film. In addition, a priming layer can be arranged on the transfer layer, the priming layer also being transferred in the embossing operation and for example promoting the adhesion of the transfer layer on the embossed substrate. The priming layer can be for example in the form of an adhesive layer, preferably a thermally activatable adhesive layer. The adhesive layer can be of a thickness of less than 10 μm, preferably in the range of between 0.5 and 2 μm. The adhesive layer can however also be formed from a cold adhesive or a UV hardenable adhesive. It is however also possible for the transfer layer itself to have components which provide for the adhesion of the transfer layer on the embossed substrate.

Further advantageous configurations are recited in the appendant claims.

It can be provided that an embossing film with a geometrically structured, electrically conductive transfer layer is used.

It can however also be provided that an embossing film with an electrically conductive transfer layer over its full surface area is used and the transfer layer is structured by a structure punch in the transfer on to the silicon wafer. In that case the surface structure of the structure punch determines the outline contours of the transferred transfer layer. The regions of the transfer layer that are not required remain on the embossing film after the embossing operation and are discarded.

It is possible for the transfer layer to be transferred by stroke embossing.

It is further possible for the transfer layer to be transferred by rolling embossing.

It is also possible for the conductor tracks to be produced in more than one embossing step. It can also be provided that the conductor tracks are embossed in portion-wise manner.

It can be provided that transfer layers of different material and/or involving different electrical conductivity and/or thickness and/or geometrical structure and/or with a different cross-sectional profile are successively transferred. The properties of the conductor tracks can be varied in many different ways in that fashion. In particular it is possible for them to be varied region-wise, for example it is possible for regions to be formed as electrodes and regions to be formed as conductor tracks or the like. The conductor tracks can for example connect electrodes together and in that way can form series and/or parallel circuits of individual photovoltaic cells.

It is thus possible for a conductivity gradient to be produced in the conductor track by transferring two or more transfer layers, for example if the individual transfer layers involve differing conductivities.

It can be provided that the geometrical structure and/or a conductivity structure of the conductor track is or are set by the configuration of the embossing punch and/or the embossing film, as described hereinbefore. It can therefore be provided that conductor track regions are transferred by an embossing film having a structured transfer layer and/or conductor track regions are transferred by means of a structure punch by an embossing film having a transfer layer over the full surface area thereof.

It is possible for both methods to be combined together. It is possible for example to provide an embossing film, the transfer layer of which has both structured and also unstructured regions and also an embossing punch which is in the form of a structure punch in region-wise manner.

It can further be provided that the adhesion of the conductor track is locally varied by transferring two or more transfer layers. The differing adhesion can be afforded by different structuring of the transfer layer and/or a different composition for the transfer layer and/or by one or more layers of the embossing film. It is possible for example to provide layers which act as an adhesive layer or as a separation layer or which give rise to a different adhesion action as a consequence of a sintering process.

In a further advantageous configuration it can be provided that embossing films with carrier layers are used, which differ from each other at least in one property, for example thickness and/or flexibility and/or substance composition.

It is further possible to use an embossing film which does not have a release layer.

It is also possible to use an embossing film which does not have a priming layer.

With the process according to the invention it is possible for a plurality of silicon wafers to be continuously embossed in an embossing operation.

It is however also possible for a plurality of silicon wafers to be discontinuously embossed in an embossing operation.

It can advantageously be provided that a metal layer is used as the transfer layer.

It is possible to transfer a plurality of transfer layers which can generate particular effects, in conjunction with the transfer layer provided as the electrode layer.

By way of example it can be provided that the further layers are electrochromic and/or thermochromic layers or layers which can transform the wavelength of the incident light in such a way that a broader light spectrum can be utilised and/or thermal overheating of the silicon wafer is avoided.

In addition it is possible for a sintering process to be carried out after transfer of the transfer layer or transfer layers. With the sintering process it is possible for example to improve the adhesion of the transferred transfer layer on the silicon wafer and/or it is possible for organic constituents to be expelled from the transferred transfer layer. For example mutual diffusion of the mutually adjoining materials can be influenced with the parameters of sintering temperature and sintering time so that an interface layer is formed, in which the transfer layer and the silicon wafer are joined together by a connection involving intimate joining of the materials concerned.

It is possible for a sintering process to be carried out between two successive embossing operations. It is however also possible for fewer sintering processes to be provided, for example a sintering operation after the first transfer coating has been applied by embossing, and a final sintering operation.

It can be provided that the two or more sintering processes are performed at the same temperature.

It can however also be provided that the two or more sintering processes are performed at differing temperature and/or residence time.

It can be provided that the sintering temperature is set in the range of between 300° C. and 800° C.

It can further be provided that the sintering temperature is set in the range of between 450° C. and 550° C.

As tests have shown it can advantageously be provided that the sintering temperature is set to about 500° C. The sintering time can be between about 10 minutes and about 30 minutes, with the sintering temperature being maintained for about 5 minutes. It is however also possible to provide a cooling step after a sintering process or after a temperature treatment process, such as for example tempering.

It can further be provided that the sintering process and/or the temperature treatment process is carried out in an atmosphere different from air, for example in a protective gas atmosphere such as nitrogen or argon.

It is also possible to provide one or more cleaning phases between the one or more sintering processes and/or temperature treatment processes.

It can be provided that the silicon wafer is acted upon with gases and/or liquids in the cleaning phases.

The temperature regime and/or the residence time regime in the cleaning phases or in the cleaning phase can be varied to achieve an optimum cleaning effect.

It can further be provided that cleaning phases are also implemented after one or more embossing operations.

It is also possible for chemical process steps which can partially or completely initiate dissolution for example of layers to be carried out after one or more embossing operations, in which respect it is possible to set numerous process parameters such as for example the chemical composition of the substances brought into contact with the silicon wafer, the residence time, the process temperature and the process pressure.

Further optional configurations of the process according to the invention are directed to the transferable transfer layers.

It can be provided that different materials are successively transferred. Thus it is possible for inorganic layers, for example ITO, to be transferred, or also for organic layers to be transferred, in which case the organic layers can be used either as functional layers or as chemical reagents.

As a further step in the process, it can be provided that a transfer layer is applied as a concluding or sealing layer which has an individualisation for the silicon wafer, for example a hologram. In that way for example product forgeries can be prevented or the manufacturing batch or the like can be established.

It can also be provided that finally one or more protective layers is applied by embossing to protect the electrode layer or layers which have been transferred by hot embossing. The protective layer can be for example a colored or decorative layer and/or a functional layer, wherein a temperature process can then follow to improve for example intermediate layer bondings.

It can further be provided that finally an anti-adhesion layer is applied by embossing to the electrode layer or layers transferred by hot embossing.

Transfer of the above-mentioned concluding layers can be implemented over the full surface area or partially similarly to the other layers.

Finally applied layers can be colored over the entire surface area or partially. The coloring can be provided for example as decoration or as an ageing indicator.

It is also possible to provide concluding layers which are provided over their full surface area or partially with an indicator which for example gives information about ageing and/or fitness for use and which is not based on a color effect. For example the indicator can be in the form of an RFID tag.

It is provided that, after the application of the concluding layer, no temperature process is carried out or one or more temperature processes are carried out at low temperatures to improve for example intermediate layer adhesion properties.

Further advantageous configurations are directed to the embossing film. To carry out the process there is provided an embossing film, in particular a hot embossing film, which has a structured, electrically conducting transfer layer. The term ‘structuring’ is used in this respect in the widest sense so that a transfer layer of equal thickness, covering the entire surface area involved, can also be provided with a structuring, for example a surface structuring.

It can be provided that the transfer layer is geometrically structured. Such a transfer layer can be in the form of a pattern of conductor tracks, that is to say it includes at least one region in which the material of the transfer layer is removed.

It can be provided that the transfer layer is structured by a printing process and/or a vapor deposition process with a mask with a subsequent structuring process (for example etching).

It can also be provided that the embossing film is segmented, that is to say segments which can differ in respect of their layers and/or their layer sequence.

It can preferably be provided that the transfer layer is in the form of a metal layer. The metal layer can be formed both from a single metal and also from a metal alloy.

It is possible for the metal layer to be formed from metal particles. The metal particles can also be very small particles in the nanometer range which in the technical literature are also referred to as clusters. Clusters of that kind can have material properties which differ fundamentally from the material properties of larger particles.

It is possible for the metal particles to be of approximately equal dimensions, in which respect the distribution of the dimensions can for example follow a bell curve, that is to say a Gaussian distribution. It can thus be assumed for example after the sintering process that regions of equal size of different metals are present in the electrode if a mixture of two or more metals or metal alloys was transferred.

It is however also possible for the metal particles to be of different dimensions. It is thus possible for example to assume after the sintering process that regions of differing size of different metals are present in the electrode if a mixture of at least two metals or metal alloys was transferred.

It can further be provided that the concentration of the metal particles in the metal layer is constant.

It can however also be provided that the concentration of the metal particles in the metal layer is not constant.

Although the use of a metallic transfer layer is preferred, it is however possible, instead of ‘metal’ or ‘metal particle’, also to provide non-metallic conductive material, for example what are referred to as ‘nanotubes’ of carbon or conductive plastic material. If that is the case the temperatures and the other process conditions of the subsequent steps are to be appropriately adapted.

It is possible for the embossing film to have a plurality of release layers.

It can further be provided that the embossing film has a plurality of priming layers.

It is also possible that the release layers and/or the priming layers are not formed over the entire surface area involved. In that way for example different regions of the transfer layer can be transferred depending on the respective embossing conditions.

In using the above-described process or the embossing film it is possible to provide a photovoltaic cell based on a silicon wafer, on the surface of which there is an electrically conductive, structured transfer layer of an embossing film. This therefore involves a photovoltaic cell which is built up on a silicon wafer and the uppermost, electrically conductive layer of which is formed from the transfer layer.

### BRIEF DESCRIPTION OF THE DRAWINGS

The invention is now described in greater detail with reference to the Figures in which:

FIGS. 1a and b show diagrammatic views in section of manufacturing steps of a first embodiment,

FIGS. 2a and b show diagrammatic views in section of manufacturing steps of a second embodiment,

FIG. 3 shows a diagrammatic view in section of a third embodiment,

FIG. 4 shows a diagrammatic view in section of a fourth embodiment,

FIG. 5 shows a diagrammatic plan view of a fifth embodiment,

FIG. 6 shows a diagrammatic view in section of a sixth embodiment, and

FIGS. 7a and b show diagrammatic views in section of manufacturing steps of a seventh embodiment.

### DETAILED DESCRIPTION OF THE PREFERRED EMBODIMENTS

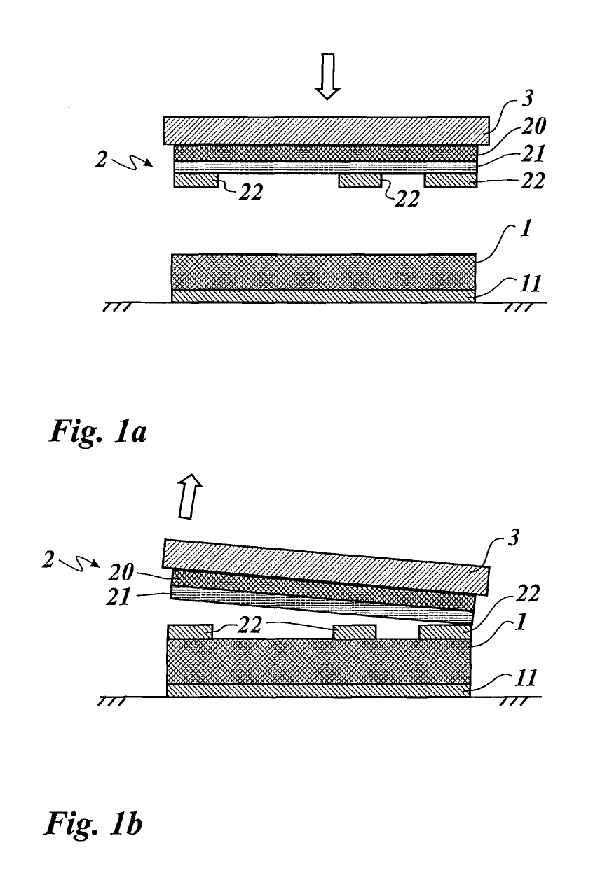

FIG. 1 shows a doped and treated silicon wafer 1 with a first electrode layer 11 at its rear side, which is suitable in known fashion by doping for constructing a photovoltaic cell.

A hot embossing film 2 is formed from a carrier film 20, a release layer 21 and an electrically conductive transfer layer 22, the hot embossing film being carried on a heated embossing punch 3.

In this case the rear side of the carrier film 20 faces towards the front side of the embossing punch 3. The front side of the hot embossing film 2 which at the same time forms the front side of the transfer layer 22 faces towards the top side of the silicon wafer 1 and is brought into contact therewith during the embossing process. In that way the transfer layer 22 is transferred on to the top side of the silicon wafer 1, as shown in FIG. 1b, and there forms conductor tracks which can be used as electrode regions and/or contact regions and/or other electrically conductive regions.

After transfer of the transfer layer 22 the embossing punch 3 is lifted off, with the release layer 21 assisting with separation of the transfer layer 22 from the hot embossing film 2.

The transfer layer 22 can be a part-metallic layer, for example of gold, silver, aluminum, copper or an alloy of those metals in an organic matrix which is provided as an adhesive for bonding of the metallic components. It can be structured as desired in manufacture of the hot embossing film 2 so that for example conductor tracks or electrode regions for forming a second electrode layer can be shaped on the silicon wafer 1.

It is however also possible to use an electrically conductive organic layer. The transfer layer 22 can be applied to the hot embossing film in known manner by sputtering, vapor deposition or printing. If sputtering or vapor deposition is used, application of a priming layer can then be implemented to achieve good adhesion for the transfer layer 22 on the silicon wafer 1. In that case a metallic transfer layer can be galvanically reinforced in one of the process steps, as described for example in EP 0 385 995 B1.

The carrier film can be formed for example from polyester of a thickness of between 19 μm and 50 μm. In the embodiment illustrated in FIGS. 1a and b the carrier film is of a thickness of about 23 μm. The release layer is not transferred in this embodiment. It can however also be provided that the release layer is at least partially transferred and for example goes into the gaseous phase in a subsequent sintering process. This embodiment does not involve the provision of a priming layer serving as an adhesive layer. It can however also be provided that at least one priming layer is simultaneously transferred partially or over the full surface area involved.

Manufacture of the hot embossing film can advantageously be effected in a roll-to-roll process. In that respect the transfer layer can be modified in many different ways.

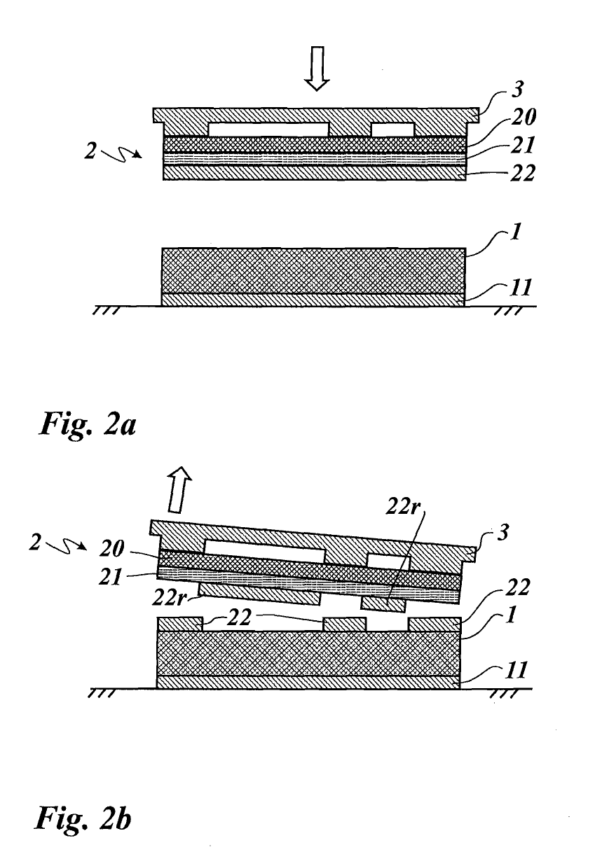

FIGS. 2a and b now show a second embodiment in which the transfer layer 22 of the hot embossing film 2 is provided over the entire surface area (FIG. 2a) and, as in the embodiment shown in FIGS. 1a and b, there is no priming layer. The embossing punch 3 has a surface structure corresponding to the conductor structure to be transferred, wherein the regions between the conductor tracks are of a recessed nature so that the surface of the embossing punch 3 is in contact with the hot embossing film only in the regions of the conductor tracks.

As shown in FIG. 2b, in the embossing operation, of the transfer layer 22, only the regions arranged on the raised regions of the embossing punch 3 are transferred on to the silicon wafer 1. Upon separation of the embossing punch 3 from the silicon wafer 1 those regions remain on the silicon wafer 1. Regions 22r of the transfer layer 22, that are arranged over the recessed regions of the embossing punch 3, remain on the hot embossing film 2 and are detached therewith.

The process shown in FIGS. 2a and b can enjoy advantages for test implementations and small-scale series and can advantageously be used whenever the manufacturing costs of the embossing punch are lower than the manufacturing costs of a hot embossing film provided with a structured transfer layer. As described hereinbefore it can be provided that the release layer is at least partially transferred and for example goes into the gaseous phase in a subsequent sintering procedure. In addition, as also described hereinbefore, it can be provided that one or more priming layer or layers which are partial or which cover the entire surface area involved are additionally transferred.

In the above-described embodiments, a sintering process can be carried out after transfer of the transfer layer in order to permanently join the transferred transfer layer to the silicon wafer 1 and to provide a good electrical contact. For example it can be provided that sintering is effected for between about 10 and 30 minutes and a temperature of about 500° C. is maintained in that case for about 5 minutes. In that case organic constituents of the transfer layer are expelled and for example a metallic electrode is produced.

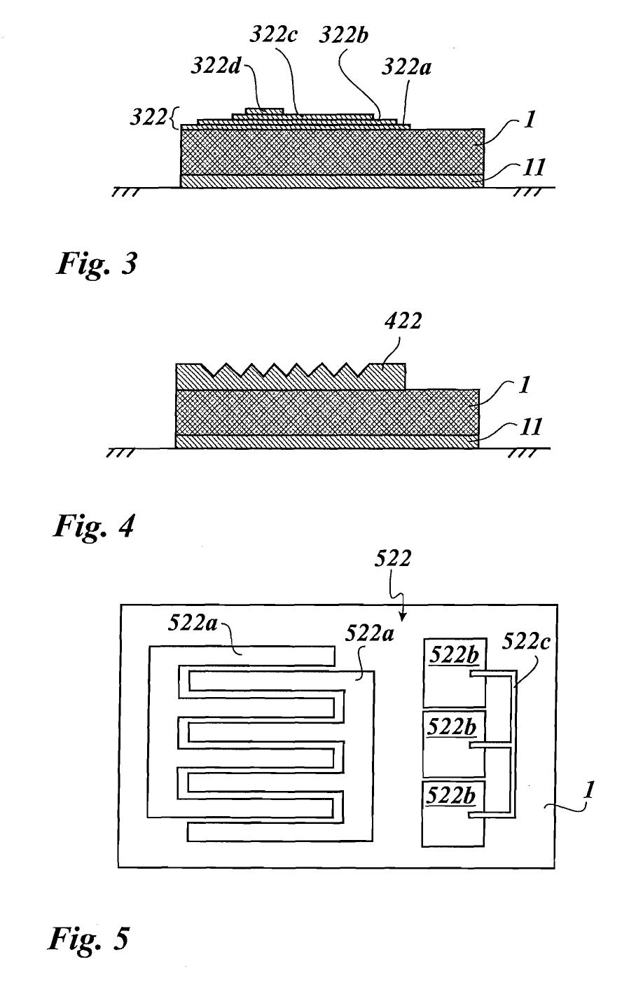

FIG. 3 now shows a third embodiment in which a transfer layer 322 formed from four transfer layer portions 322a through 322d is transferred on to the silicon wafer 1. In the FIG. 3 embodiment the transferred transfer layer portions 322a through 322d are structured differently so that for example a conductivity profile can be produced in the conductor tracks or electrode regions.

It can however also be provided that the transfer layer portions 322a through 322d are made from different materials. For example the uppermost, outward transfer layer portion 322d can be of a particularly weather-resistant nature, the innermost transfer layer portion 322a can be of a particularly firmly adhering nature and the two interposed transfer layer portions 322b and 322c can have a high conductivity. In this example the innermost transfer layer portion 322a or the inner layer composite could include for example aluminum while the outwardly disposed transfer layer portion 322d or the outer layer composite could contain chromium.

A sintering process can be carried out after each layer application operation, in which respect it can further be provided that the sintering temperature and the sintering time are varied for each layer application operation.

FIG. 4 shows a fourth embodiment in which the cross-section of a transfer layer 422 is structured. In the FIG. 4 embodiment the side of the transfer layer 422 that is remote from the silicon wafer 1 is provided with a sawtooth-shaped surface structure. With the proposed use of a hot embossing film, such structuring is possible in accurate register relationship, for example by way of a replication layer which is integrated into the hot embossing film and in which the negative surface profile is shaped. It can also be provided that the negative surface profile is shaped directly in the carrier film 20.

FIG. 5 now shows a plan view of a fifth embodiment which for example illustrates the possible configuration options of the process according to the invention.

Three transfer layer portions 522a through 522c which give conductor tracks 522 are successively transferred on to the silicon wafer 1. In the FIG. 5 embodiment the transfer layer portions 522a and 522b are in one plane, and equally the regions of the transfer layer portion 522c which do not cover over regions of the transfer layer portions 522b. The transfer layer portions 522b may for example be second electrode layers which are in opposite relationship to the first electrode layers 11. The transfer layer portion 522c can be conductor tracks which electrically connect the transfer layer portions 522b together. The transfer layer portions 522b and 522c can be made from different materials so that the material properties can be optimally adapted to the functions of ‘electrode’ and ‘line connection’.

The transfer layer portion 522a can form for example a capacitor or an antenna arrangement to perform an additional function, for example a capacitor or an antenna for an RFID chip integrated into the silicon wafer. For example the material and/or the cross-sectional structure and/or the surface structure of the transfer layer portion 522a can be optimised for that function. A surface structure which involves multiple subdivision can for example be of a substantially larger surface area than a smooth surface structure and therefore can have better electrical conductivity for high frequencies, that is to say in regard to making use of what is referred to as the skin effect.

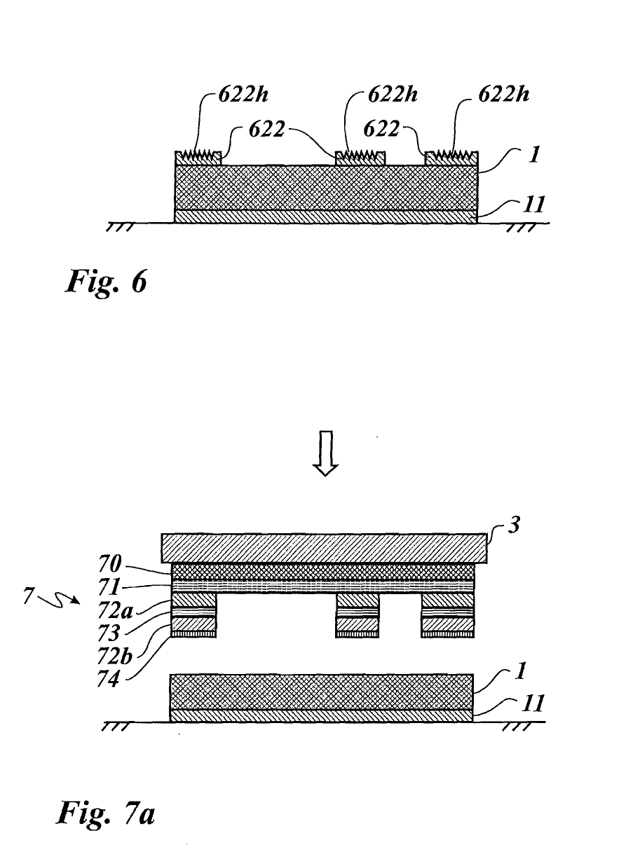

FIG. 6 now shows a further embodiment in which electrode layers 622 are applied by embossing on the front side of the silicon wafer 1 having a first electrode layer 11 at its rear side, the electrode layers 622 being personalised. Personalisation is effected after transfer of the electrode layer by embossing a surface profile, for example a hologram, into the surface of the electrode layer 622, that is remote from the silicon wafer 1. Personalisation can be provided for example to apply a tamper-proof authenticity certificate.

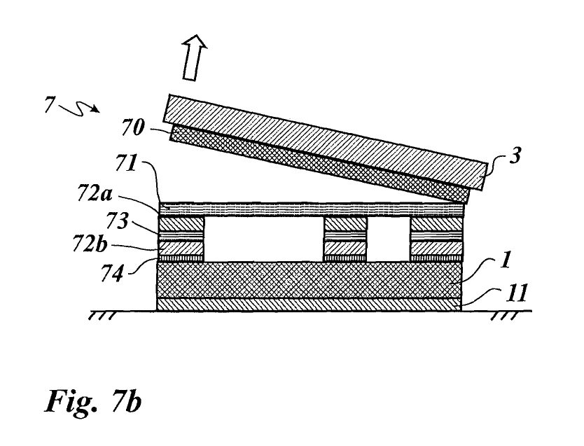

FIGS. 7a and 7b now show process steps for constructing multi-layer second electrode layers.

FIG. 7a shows a hot embossing film 7 which is pressed with the embossing punch 3 on to the silicon wafer 1. The hot embossing film 7 is made up of a carrier film 70, a release layer 71, a first electrically conductive transfer layer 72a, an intermediate layer 73, a second electrically conductive transfer layer 72b and a priming layer 74.

In the hot embossing operation the two transfer layers 72a, 72b are transferred jointly, as shown in FIG. 7b, wherein the transfer operation is again followed by a sintering procedure which joins the two transfer layers both to each other and also to the surface of the silicon wafer 1.

The release layer 71 is so set up that it does not remain on the hot embossing film 7 but on the electrode layer. The release layer 71 is therefore only removed in the sintering step.

1. A process for the production of conductor tracks on a silicon wafer intended for photovoltaic cells, wherein
at least one electrically conductive transfer layer is transferred completely or region-wise on to the surface of the silicon wafer by an embossing film.

2. A process as set forth in claim 1, wherein an embossing film with a geometrically structured, electrically conductive transfer layer is used.

3. A process as set forth in claim 1, wherein an embossing film with an electrically conductive transfer layer over its full surface area is used and the transfer layer is structured by a structure punch in the transfer on to the silicon wafer.

4. A process as set forth in claim 1, wherein the conductor tracks are produced in more than one embossing step.

5. A process as set forth in claim 4, wherein transfer layers of different material and/or involving different electrical conductivity and/or with a different geometrical structure and/or with a different cross-sectional profile are successively transferred.

6. A process as set forth in claim 5, wherein a conductivity gradient is produced in the conductor track by transferring two or more transfer layers.

7. A process as set forth in claim 1, wherein the geometrical structure and/or a conductivity structure of the conductor track is or are set by the configuration of the embossing punch and/or the embossing film.

8. A process as set forth in claim 4, wherein the adhesion of the conductor track is locally varied by transferring two or more transfer layers.

9. A process as set forth in claim 4, wherein embossing films with carrier layers are used, which differ from each other at least in one property.

10. A process as set forth in claim 1, wherein a sintering process is carried out after transfer of the transfer layer or transfer layers.

11. A process as set forth in claim 10, wherein a sintering process is carried out between two successive embossing operations.

12. A process as set forth in claim 11, wherein two or more sintering processes are performed at differing temperature and/or residence time.

13. A process as set forth in claim 10, wherein the sintering temperature is set in the range of between 300° C. and 800° C.

14. A process as set forth in claim 13, wherein the sintering temperature is set in the range of between 450° C. and 550° C.

15. A process as set forth in claim 1, wherein the conductor track is embossed thereon with at least one protective layer.

16. A process as set forth in claim 1, wherein a transfer layer is applied as a concluding layer having an optically variable element.

17. An embossing film, for carrying out the process as set forth in claim 1, wherein the embossing film has a structured electrically conductive transfer layer.

18. An embossing film as set forth in claim 17, wherein the transfer layer is geometrically structured.

19. An embossing film as set forth in claim 17, wherein the transfer layer is structured in its cross-section.

20. An embossing film as set forth in claim 17, wherein the transfer layer is in the form of a metal layer.

21. An embossing film as set forth in claim 20, wherein the metal layer is formed from metal particles.

22. An embossing film as set forth in claim 17, wherein the transfer layer is formed from carbon nanotubes and/or from electrically conductive polymers.

23. An embossing film as set forth in claim 17, wherein the embossing film has one or more release layers.

24. An embossing film as set forth in claim 17, wherein the embossing film has one or more priming layers.

25. An embossing film as set forth in claim 23, wherein the release layers and/or the priming layers are not provided over the full surface area.

26. A photovoltaic cell based on a silicon wafer, to the surface of which there is applied an electrically conductive structured transfer layer of an embossing film, as set forth in claim 17.
